(19) United States
(12) Patent Application Publication
(10) Pub. No.: US 2006/0038592 A1
(43) Pub. Date: Feb. 23, 2006

(54) Maximum/minimum value output circuit

(75) Inventors: Fumihiro Inoue, Atsugi-Shi (JP); Masami Hakoda, Atsugi-Shi (JP); Kyouzou Makime, Atsugi-Shi (JP)

Correspondence Address: LADAS & PARRY LLP, 224 SOUTH MICHIGAN AVENUE, SUITE 1600, CHICAGO, IL, 60604, US

(73) Assignee: MITSUMI ELECTRIC CO., LTD.

(21) Appl. No.: 11/065,939

(22) Filed: Feb. 25, 2005

(30) Foreign Application Priority Data
Aug. 23, 2004 (JP) 2004-242472

(51) Int. Cl. H03B 1/00

(52) U.S. Cl. 327/108

(57) ABSTRACT

A maximum/minimum value output circuit that selectively outputs a maximum/minimum value signal from plural input signals is disclosed. The maximum/minimum value output circuit includes plural input transistors having bases that are configured to input differing input signals, and collector-emitter structures that are connected through parallel connection; a current mirror circuit that outputs a current according to currents at the input transistors; and an output transistor having a collector-emitter structure to which a current is supplied according to the output current of the current mirror circuit, and a base that outputs a signal corresponding to a maximum or minimum level input signal of the differing input signals input to the bases of the input transistors.

### BACKGROUND OF THE INVENTION

1. Field of the Invention

The present invention relates to a maximum/minimum value output circuit that selectively outputs a maximum or minimum level signal out of plural input signals.

2. Description of the Related Art

A cold cathode fluorescent lamp (CCFL) may be used as a backlight for a liquid crystal display monitor, for example. A drive system for driving a cold cathode fluorescent lamp includes a protection system for protecting the cold cathode fluorescent lamp by detecting an abnormality of the cold cathode fluorescent lamp.

In a protection system according to the prior art, a state of the cold cathode fluorescent lamp is detected by determining a maximum value of an applied voltage or a supplied current (drive current) of the cold cathode fluorescent lamp. In such a system, a peak of the applied voltage or supplied current of the cold cathode fluorescent lamp is held, and the peak hold value as the maximum value is output as a direct current. For example, Japanese Laid-Open Patent Publication No. 6-267674 and Japanese Laid-Open Patent Publication No. 2002-134293 disclose technology relating to such a system.

The protection circuit for a cold cathode fluorescent lamp according to the prior art is arranged to detect the state of the cold cathode fluorescent lamp by holding the peak of an applied voltage or a drive current of the cold cathode fluorescent lamp to detect the maximum value of the applied voltage or the drive current, and supplying the detected value to a comparator to compare the detected value with a reference voltage, for example. In this case, additional circuits such as a peak hold circuit may have to be provided as a prior stage circuit for the comparator, and thereby, the circuit configuration may be complicated.

### SUMMARY OF THE INVENTION

Accordingly, it is an object of the present invention to provide a maximum/minimum value output circuit that is capable of outputting a maximum or minimum value with a simple structure that does not require the implementation of additional circuits.

According to an aspect of the present invention, a maximum/minimum value output circuit is provided that selectively outputs a maximum/minimum value signal, the circuit including:
plural input transistors having bases that are configured to input differing input signals, and collector-emitter structures that are connected through parallel connection;
a current mirror circuit that outputs a current according to currents at the input transistors; and
an output transistor having a collector-emitter structure to which a current is supplied according to the output current of the current mirror circuit, and a base that outputs a signal corresponding to a maximum or minimum level input signal of the differing input signals input to the bases of the input transistors.

According to a preferred embodiment of the present invention, the input transistors and the output transistor correspond to bipolar transistors.

According to another preferred embodiment of the present invention, the current mirror circuit corresponds to a MOS transistor.

According to another preferred embodiment of the present invention, the input transistors and the output transistor correspond to transistors having identical characteristics.

According to an aspect of the present invention, a switching characteristic of a transistor realized by plural input transistors, a current mirror circuit, and an output transistor is used to selectively output a signal corresponding to a maximum level signal of plural input signals.

### BRIEF DESCRIPTION OF THE DRAWINGS

FIG. 1 is a block diagram showing an exemplary configuration of a cold cathode fluorescent lamp lighting system according to an embodiment of the present invention;

FIG. 2 is a block diagram showing an exemplary configuration of a drive IC;

FIG. 3 is a circuit diagram showing an exemplary configuration of a PWM control unit;

FIG. 4 is a circuit diagram showing an exemplary configuration of a protection circuit unit;

FIG. 5 is a circuit diagram showing an exemplary configuration of a maximum value output circuit;

FIG. 6 is a diagram illustrating an exemplary operation of the maximum value output circuit;

FIG. 7 is a circuit diagram showing another exemplary configuration of the maximum value output circuit; and

FIG. 8 is a circuit diagram showing an exemplary configuration of a minimum value output circuit.

### DETAILED DESCRIPTION OF THE PREFERRED EMBODIMENTS

In the following, principles and embodiments of the present invention are described with reference to the accompanying drawings.

According to an embodiment, a maximum value output circuit may be used in a cold cathode fluorescent lamp lighting system.

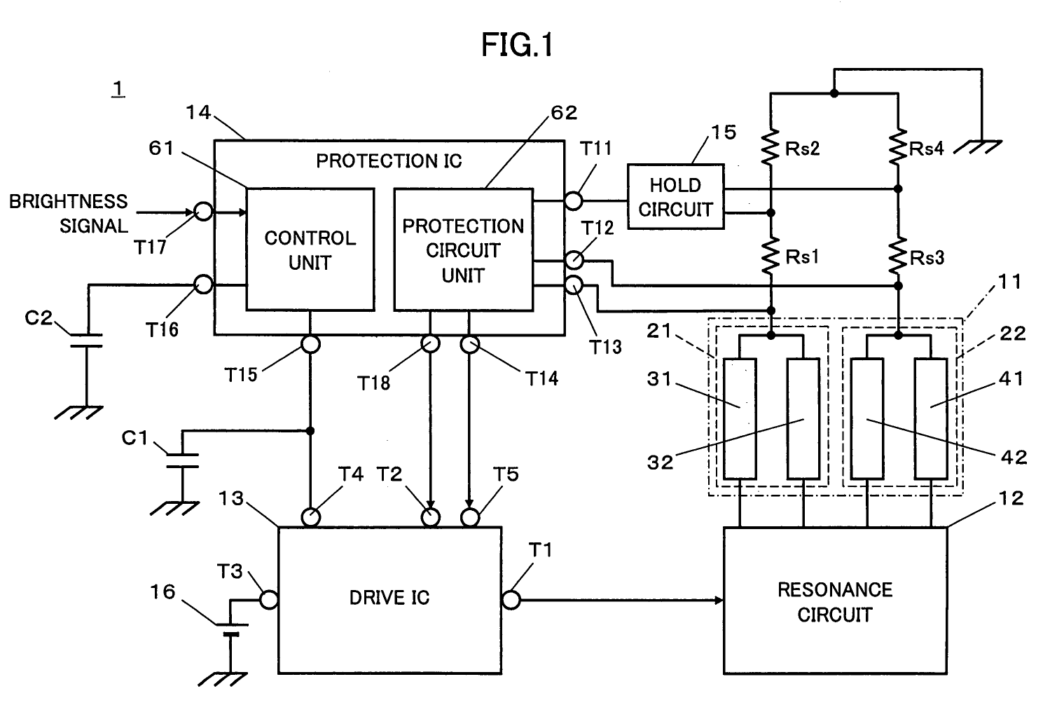

FIG. 1 is a block diagram showing an exemplary configuration of a cold cathode fluorescent lamp lighting system according to an embodiment of the present invention.

The cold cathode fluorescent lamp lighting system 1 of the present embodiment may correspond to a system that is used as a backlight of a liquid crystal display monitor, for example. As is shown in FIG. 1, the cold cathode fluorescent lamp lighting system 1 includes a cold cathode fluorescent lamp unit 11, a resonance circuit unit 12, a drive IC (Integrated Circuit) 13, a protection IC 14, a peak hold circuit 15, a reference voltage source 16, and capacitors C1 and C2.

The cold cathode fluorescent lamp unit 11 includes two cold cathode fluorescent lamp pairs 21 and 22 that are arranged to be parallel. The cold cathode fluorescent lamp pair 21 includes two cold cathode fluorescent lamps 31 and 32 that are arranged to be parallel, and the cold cathode fluorescent lamp pair 22 includes two cold cathode fluorescent lamps 41 and 42 that are arranged to be parallel.

It is noted that the ends of the cold cathode fluorescent lamps 31, 32, 41, and 42 on one side are connected to the resonance circuit 12. The ends of the cold cathode fluorescent lamps 31 and 32 on the other side are grounded via detection resistors Rs1 and Rs2 in series, the ends of the cold cathode fluorescent lamps 41 and 42 on the other side are grounded via detection resistors Rs3 and Rs4 in series.

The cold cathode fluorescent lamps 31, 32, 41, and 42 and the resonance circuit 12 realize a resonance circuit system. When a voltage having a predetermined frequency (e.g., 50 kHz) is applied across the cold cathode fluorescent lamps 31, 32, 41, and 42, a drive current is supplied to the cold cathode fluorescent lamps 31, 32, 41, and 42, and the cold cathode fluorescent lamps 31, 32, 41, and 42 are lit. When a voltage having a lower or higher frequency (e.g., 100 kHz) than the predetermined frequency is applied, the supplying of the drive current to the cold cathode fluorescent lamps 31, 32, 41, and 42 is stopped so that the cold cathode fluorescent lamps 31, 32, 41, and 42 are turned off.

It is noted that a drive signal having a predetermined frequency is supplied to the resonance circuit 12 from the drive IC 13. The resonance circuit 12 includes a resistor, a capacitor, and a transformer, for example, to provide a capacitance and an inductance of the circuit. According to the present example, the resonance circuit 12 is arranged to resonate in response to a drive signal supplied from the drive IC 13, and supply drive power to the cold cathode fluorescent lamp unit 11.

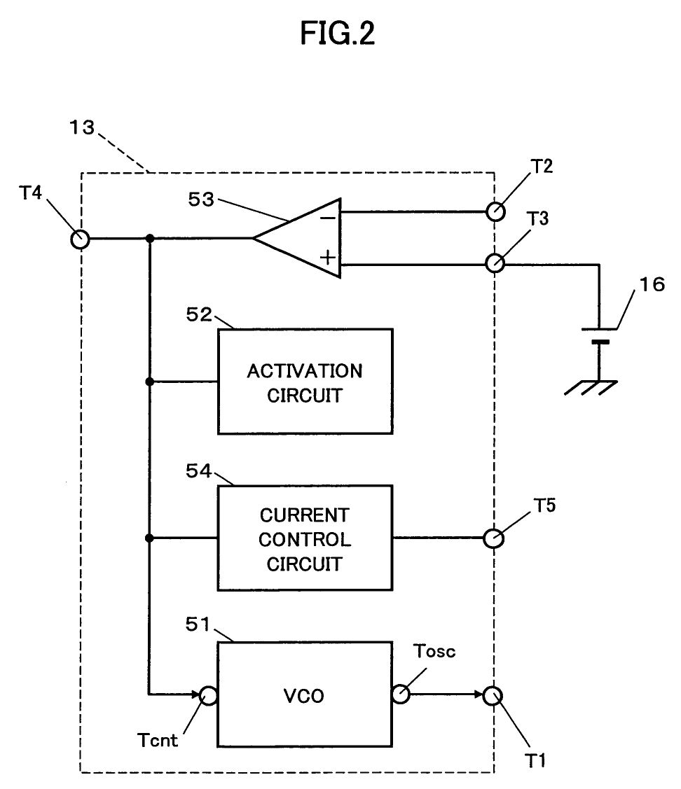

FIG. 2 is a block diagram showing a configuration of the drive IC 13.

According to FIG. 2, the drive IC 13 includes a voltage control oscillation (VCO) circuit 51, an activation circuit 52, an error amplifier 53, and a voltage control circuit 54.

The voltage control oscillation circuit 51 includes a control terminal Tcnt and an oscillation output terminal Tosc. The control terminal Tcnt of the voltage control oscillation circuit 51 is connected to the activation circuit 52, the error amplifier 53, the voltage control circuit 54, and a terminal T4. The voltage control oscillation circuit 51 is arranged to output from the output terminal Tosc an oscillation output having a frequency according to the applied voltage of the control terminal Tcnt.

It is noted that the output terminal Tosc of the voltage control oscillation circuit 51 is connected to an output terminal T1 of the drive IC 13, and the oscillation output of the voltage control oscillation circuit 51 is output from the output terminal T1 to the resonance circuit 12.

The activation circuit 52 controls the control voltage for the voltage control oscillation circuit 51 to speed up the lighting of the cold cathode fluorescent lamps 31, 32, 41, and 42 when the power is switched on, for example.

The error amplifier 53 is arranged such that its inverting input terminal is connected to a terminal T2, and its non-inverting input terminal is connected to a terminal T3. It is noted that an average value signal is supplied to the terminal T2 from the protection IC 14, and a reference voltage is supplied to the terminal T3 from a reference voltage source 16. An output of the error amplifier 53 is arranged to be supplied to the control terminal Tcnt of the voltage control oscillation circuit 51 and the terminal T4.

The voltage control circuit 54 is connected to a terminal T5. The terminal T5 is connected to a terminal T14 of the protection IC 14, and is arranged to receive a stop signal from the protection IC 14. In response to receiving a stop signal from the protection IC 14, the voltage control circuit 54 sets the control terminal Tcnt of the voltage control oscillation circuit 51 to high-level. According to the present example, once the output of voltage control oscillation circuit 51 is set to high-level, the voltage control circuit 54 is arranged to maintain the high-level output until the system operation is reset through power switch-off, for example.

As is shown in FIG. 1, the terminal T4 is connected to a terminal T15 of the protection IC 14. A capacitor C1 is provided between ground and the connection point between the terminals T4 and T15. According to the present example, the control voltage that is applied to the control terminal Tcnt of the voltage control oscillation circuit 51 is controlled by the charged voltage of the capacitor C1, and in this way, the oscillation frequency of the oscillation output of the voltage control oscillation circuit 51 is controlled.

As is shown in FIG. 1, the protection IC includes a PWM (pulse width modulation) control unit 61 and a protection circuit unit 62. The PWM control unit 61 corresponds to a circuit for conducting PWM control on the oscillation state of the voltage control oscillation circuit 51 of the drive IC 13.

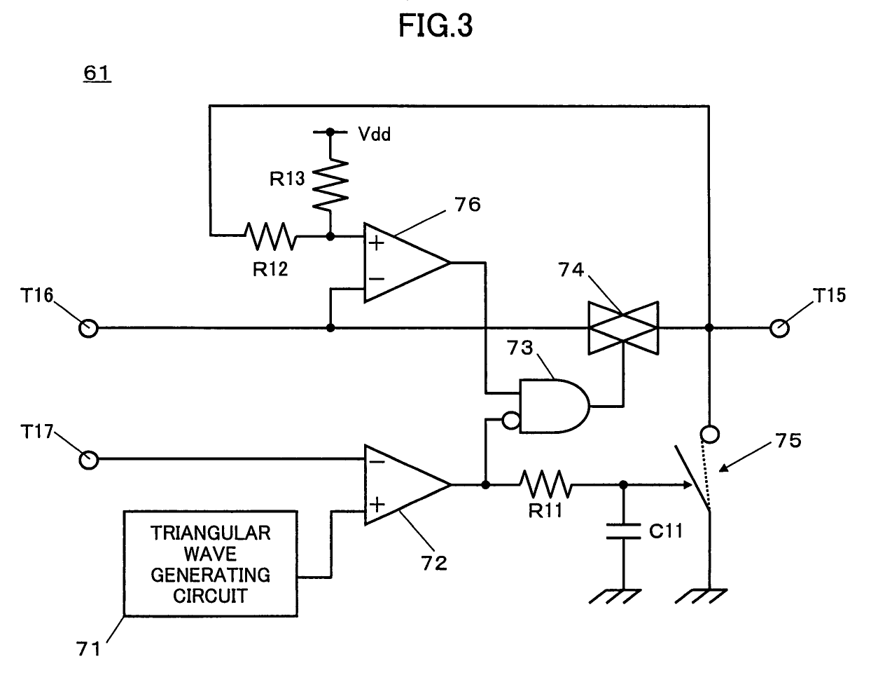

FIG. 3 is a block diagram showing an exemplary configuration of the PWM control unit 61.

According to FIG. 3, the PWM control unit 61 includes a triangular wave generating circuit 71, a comparator 72, a gate circuit 73, an analog switch 74, a discharge switch 75, a comparator 76, resistors R11, R12, and R13, and a capacitor C11.

It is noted that a brightness signal is supplied from the outside to a terminal T17 of the protection IC 14. The brightness signal supplied to the terminal T17 is then supplied to an inverting terminal of the comparator 72. A triangular wave from the triangular wave generating circuit 71 is supplied to a non-inverting terminal of the comparator 72. The comparator 72 is arranged to compare the brightness signal and the triangular wave supplied to its respective terminals, and generate a pulse having a pulse width according to the frequency of the triangular wave and the signal level of the brightness signal. For example, when the triangular wave is higher than the brightness signal, the comparator 72 outputs a high-level pulse, and when the triangular wave is lower than the brightness signal, the comparator 72 outputs a low-level pulse.

The output pulse of the comparator 72 is supplied to the switch 75 via a delay circuit that is realized by the resistor R11 and the capacitor C11. The output pulse of the comparator 72 is also supplied to the gate circuit 73. The switch 75 is provided between a terminal T15 and ground and is arranged to be switched by a delayed pulse of the output pulse of the comparator 72 that is delayed by a delay time determined by the resistor R11 and the capacitor C11. For example, the switch 75 is turned off when the output pulse of the comparator 72 corresponds to a low-level pulse so that the terminal T15 may be disconnected from ground to enable the capacitor C11 to be charged, and the switch 75 is turned on when the output pulse of the comparator 72 corresponds to a high-level pulse so that the terminal T15 is shorted to ground to realize discharge of the capacitor C1.

The gate circuit 73 inputs an inverted pulse of the output pulse of the comparator 72. An output of the comparator 76 is also supplied to the gate circuit 73. The gate circuit 73 is arranged to output a logical product (AND) of the inverted output of the output pulse of the comparator 72 and the output of the comparator 76. The output of the gate circuit 73 is then supplied to the analog switch 74.

The analog switch 74 is provided between terminals T15 and T16, and is arranged to be switched according to the output of the gate circuit 73 to connect or disconnect the terminals T15 and T16. For example, the analog switch 74 is turned on when the output of the gate circuit 73 corresponds to a high-level output so that the terminals T15 and T16 is shorted, and the analog switch 74 is turned off when the output of the gate circuit 73 corresponds to a low-level output so that the terminals T15 and T16 are disconnected.

The comparator 76 is arranged such that its inverting input terminal is connected to the terminal T16, and its non-inverting input terminal is connected to a connection point between the resistors R12 and R13. The resistor R12 is arranged such that one of its ends is connected to the non-inverting input terminal of the comparator 76, and its other end is connected to the terminal T15. The resistor R13 is arranged such that one of its ends is connected to a connection point between the non-inverting input terminal of the comparator 76 and one end of the resistor R12, and its other end is connected to a power source that supplies a power source voltage Vdd.

The comparator 76 is arranged to compare the potential at the connection point between the resistors R12 and R13 and the potential at the terminal T16. For example, the comparator 76 is arranged to output a high-level output, when the potential at the connection point between the resistor R12 and R13 is higher than the potential at the terminal T16, and output a low-level output when the potential at the connection point between the resistors R12 and R13 is lower than the potential at the terminal T16.

In the following, exemplary operations processes of the PWM control unit 61 are described.

According to the present example, first, when the output pulse of the comparator 72 is set to high-level, the switch 74 is turned off so that the terminals T15 and T16 are disconnected. In turn, the capacitors C1 and C2 are disconnected.

Then, the high-level output pulse of the comparator 72 is delayed by the resistor R11 and the capacitor C11, and the switch 75 is turned on after a slight delay from the time the output pulse of the comparator 72 is set to high-level. When the switch 75 is turned on, the capacitor C1 connected to the terminal T15 is discharged. It is noted that when the capacitor C1 is discharged, the potential of the terminal T15 decreases.

When the level of the triangular wave generated at the triangular wave generating circuit 71 decreases so that the output pulse of the comparator 72 is set to low-level, the switch 75 is turned off after a slight delay designated by the resistor R11 and the capacitor C11. When the switch 75 is turned off, the capacitor C1 is charged by the potential of the terminal T4 of the drive IC 13.

When the capacitor C1 is charged, the potential of the terminal T15 increases, and when the potential of the terminal T15 increases, the potential of the non-inverting input terminal of the comparator 76 increases.

When the potential of the non-inverting input terminal of the comparator 76 increases to a level exceeding the potential of the terminal T16 (i.e., the charge voltage of the capacitor C2), the output of the comparator 76 is set to high-level. When the output of the comparator 76 is set to high-level, the output of the gate circuit 73 is set to high-level, and the analog switch 74 is turned on. When the analog switch 74 is turned on, the capacitors C1 and C2 are connected to the terminal T4.

As is described above, according to the present example, when the charge voltage of the capacitor C1 reaches a desired voltage with respect to the charge voltage of the capacitor C2, the analog switch 74 is turned on so that the capacitors C1 and C2 are connected to the terminal T4. In this way, overshooting may be prevented in the capacitor C1 during voltage charge.

When the level of the triangular wave of the triangular wave generating circuit 71 exceeds the level of the brightness signal and the output of the comparator 72 is set to high-level, the output of the gate circuit 73 is set to low-level and the analog switch 74 is turned off. When the analog switch is turned off, the capacitor C2 holds the potential of the terminal T4 of the drive IC 13. The switch 75 is turned on after a slight delay from the time the analog switch 74 is turned off so that the capacitor C1 is discharged. In this case, since the analog switch 74 is already turned off, the potential of the terminal T4 is held at the capacitor C2.

As can be appreciated from the above descriptions, the potential of the terminal T4 of the drive IC 13 is pulse-controlled according to the output pulse of the comparator 72.

According to an embodiment, when the potential of the terminal T4 is pulse-driven, the drive IC 13 is arranged to be capable of intermittently switching the oscillation frequency of the oscillation output of the voltage control oscillation circuit 51 between a frequency of approximately 50 kHz and a frequency of approximately 100 kHz, for example. In this case, when the output oscillation frequency of the voltage control oscillation circuit 51 is set to approximately 50 kHz, the resonance circuit 12 resonates so that the cold cathode fluorescent lamps 31, 32, 41, and 42 are lit. When the output oscillation frequency of the voltage control oscillation circuit 51 is set to approximately 100 kHz, the power suppllied from the resonance circuit 12 to the cold cathode fluorescent lamps 31, 32, 41, and 42 is stopped, and the cold cathode fluorescent lamps 31, 32, 41, and 42 are turned off.

In the present example, power is intermittently supplied to the cold cathode fluorescent lamps 31, 32, 41, and 42 so that the brightness may be maintained at a fixed level.

According to an embodiment, the analog switch 74 is switched on when the capacitor C1 is being charged to control the connection between the capacitors C1 and C2 and adjust their respective capacities. In this way, the overshooting of the potential of the terminal T4 may be prevented so that the oscillation output of the voltage control oscillation circuit 51 of which oscillation frequency is controlled by the potential of the terminal T4 is stabilized.

In the following, the protection circuit unit 62 is described.

The protection circuit unit 62 corresponds to a circuit that detects a maximum value of an applied voltage or a supplied current of the cold cathode fluorescent lamp unit 11 to detect an abnormality of the cold cathode fluorescent lamp unit 11.

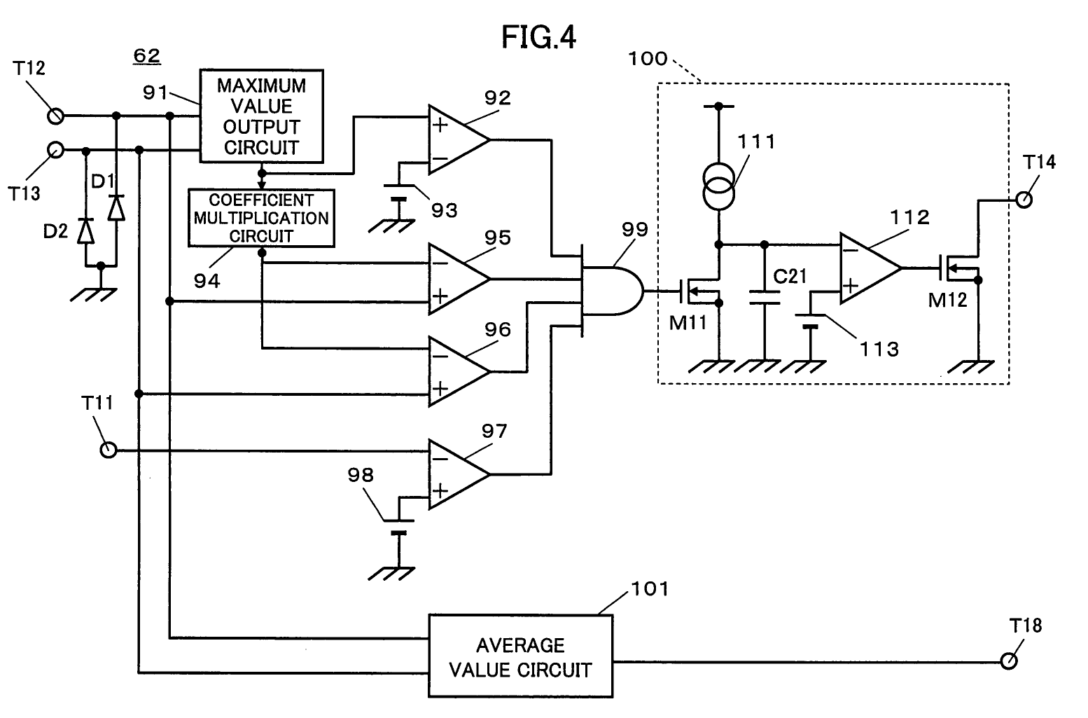

FIG. 4 is a block diagram showing an exemplary configuration of the protection circuit unit 62.

According to FIG. 4, the protection circuit unit 62 includes a maximum value output circuit 91, a comparator 92, a reference voltage source 93, a coefficient multiplication circuit 94, comparators 95, 96, and 97, a reference voltage source 98, an AND gate 99, an output circuit 100, and diodes D1 and D2.

The maximum value output circuit 91 is arranged to input detection voltages from terminals T12 and T13. The diode D1, which is provided between the terminal T12 and ground, is connected to the terminal T12 in a backward direction. The diode D2, which is provided between the terminal T13 and ground, is connected to the terminal T13 in a backward direction.

The diodes D1 and D2 are used as protective elements of the protection IC 13. The diodes D1 and D2 are arranged to conduct half-wave rectification of the detection voltages of the terminals T12 and T13, respectively, for example. Accordingly, signals that are supplied to the terminals T12 and T13 and half-wave rectified at the diodes D1 and D2 are supplied to the maximum value output circuit 91.

The maximum value output circuit 91 is arranged to selectively output the detection voltage with a higher voltage out of the detection voltages supplied from the terminals T12 and T13 as a maximum value signal.

The maximum value signal output from the maximum value output circuit 91 is then supplied to a non-inverting input terminal of the comparator 92 and the coefficient multiplication circuit 94. It is noted that a reference voltage from the reference voltage source 93 is applied to an inverting input terminal of the comparator 92. The reference voltage generated at the reference voltage source 93 corresponds to a minimum value for the maximum value signal.

The comparator 92 is arranged to set its output to high-level when the maximum value signal from the maximum value output circuit 91 is higher than the reference voltage generated at the reference voltage source 93, and set its output to low-level when the maximum value signal from the maximum value output circuit 91 is lower than the reference voltage generated at the reference voltage source 93. The output of the comparator 92 is supplied to the AND gate 99.

The coefficient multiplication circuit 94 is arranged to multiply the maximum value signal output from the maximum value output circuit 91 by 0.8, for example. In other words, the coefficient multiplication circuit 94 is arranged to output a signal representing 80% of the maximum value. The multiplied signal obtained at the coefficient multiplication circuit 94 is supplied to inverting input terminals of the comparators 95 and 96.

It is noted that the detection signal V12 that is supplied to the terminal T12 is input to the non-inverting input terminal of the comparator 95. The comparator 95 is arranged to set its output to high-level when the detection signal V12 is higher than the signal from the coefficient multiplication circuit 94 representing 80% of the maximum value, and set its output to low-level when the detection signal V12 is lower than the signal from the coefficient multiplication circuit 94 representing 80% of the maximum value.

It is noted that the detection signal V13 that is supplied to the terminal T13 is input to the non-inverting input terminal of the comparator 96. The comparator 96 is arranged to set its output to high-level when the detection signal V13 is higher than the signal from the coefficient multiplication circuit 94 representing 80% of the maximum value, and set its output to low-level when the detection signal V13 is lower than the signal from the coefficient multiplication circuit 94 representing 80% of the maximum value. The outputs of the comparators 95 and 96 are supplied to the AND gate 99.

It is noted that an output of the hold circuit 15 is supplied from a terminal T11 to an inverting input terminal of the comparator 97. The hold circuit 15 is arranged to hold a maximum voltage of the connection point between the detection resistors Rs1 and Rs2, and the maximum voltage of the connection point between the detection resistors Rs3 and Rs4. It is also noted that a reference voltage from the reference voltage source 98 is applied to the non-inverting input terminal of the comparator 97. The reference voltage generated at the reference voltage source 98 is set according to the maximum drive voltage.

The comparator 97 is arranged to set its output to low-level when the output voltage of the hold circuit 15 is higher than the reference voltage of the reference voltage source 98, and set its output to high-level when the output voltage of the hold circuit 15 is lower than the reference voltage of the reference voltage source 98. The output of the comparator 97 is supplied to the AND gate 99.

As is described above, the respective outputs of the comparators 92, 95, 96, and 97 are supplied to the AND gate 99. In turn, the AND gate 99 is arranged to output a logical product (AND) of the outputs of the comparators 92, 95, 96, and 97. According to the present example, the AND gate 99 is arranged to set its output to high-level when all the outputs of the comparators 92, 95, 96, and 97 are set to high-level, and set its output to low-level when at least one of the outputs of the comparators 92, 95, 96, and 97 is set to low-level. The output of the AND gate 99 may be supplied to the output circuit 100.

According to the present example, the output circuit 100 includes a current source 111, a comparator 112, a reference voltage source 113, a capacitor C21, and transistors M11 and M12.

It is noted that the output of the AND gate 99 is supplied to a gate of the transistor M11. In the present example, the transistor M11 corresponds to an n-channel MOS field effect transistor having a source that is grounded. The capacitor C21 is arranged to be parallel with the drain-source of the transistor M11. A charge current from the current source 111 is supplied to the connection point between the drain of the transistor M11 and the capacitor C21.

The transistor M11 is turned on when the output of the AND gate 99 is set to high-level, and is turned off when the output of the AND gate 99 is set to low-level. When the transistor M11 is turned off, a charge current is supplied from the current source 111 to the capacitor C21 so that the capacitor C21 is charged. When the transistor M11 is turned on, the electric charge of the capacitor C21 is discharged to ground via the transistor M11. In this way, the capacitor C21 is charged/discharged according to the on/off state of the transistor M11.

The charge voltage of the capacitor C21 is applied to an inverting input terminal of the comparator 112. The comparator 112 is arranged to set its output to low-level when the charge voltage of the capacitor C21 is higher than the reference voltage of the reference voltage source 113, and set its output to high-level when the charge voltage of the capacitor 21 is lower than the reference voltage of the reference voltage source 113. The output of the comparator 112 is supplied to a gate of the transistor M12.

The transistor M12 corresponds to an n-channel MOS field effect transistor of which a source is grounded, and a drain is connected to an output terminal T14. The transistor M12 is arranged to be turned on when the output of the comparator is set to high-level, and is arranged to be turned off when the output of the comparator 112 is set to low-level.

In the following, operations processes of the protection circuit unit 62 are described.

In normal operation, the outputs of all the comparators 92, 95, 96, and 97 correspond to high-level outputs, and the output of the AND gate 99 corresponds to a high-level output. When the output of the AND gate 99 corresponds to a high-level output, the transistor M11 is turned on. When the transistor M11 is turned on, the capacitor C21 is discharged so that the charge voltage of the capacitor C21 is set to low-level. When the charge voltage of the capacitor 21 is set to low-level, the output of the comparator 112 is set to high-level. When the output of the comparator 112 is set to high-level, the transistor M12 is turned on, and the potential of the terminal T14 is set to low-level.

In a case where there is an abnormality in the connection state or lighting state of the cold cathode fluorescent lamp unit 11 and the output of the maximum output circuit 91 goes below the reference voltage (i.e., minimum value for the maximum value signal), the output of the comparator 92 is set to low-level.

When the output of the comparator 92 is set to low-level, the output of the AND gate 99 is set to low-level. When the output of the AND gate 99 is set to low-level, the transistor M11 is turned off. When the transistor M11 is turned off, the capacitor C21 is charged by the current source 111. When the capacitor C21 is charged so that its charge voltage exceeds the reference voltage of the reference voltage source 113, the output of the comparator 112 is set to low-level. When the output of the comparator 112 is set to low-level, the transistor M12 is turned off and the potential of the terminal T14 is set to high-level. When the potential of the terminal T14 is set to high-level, the abnormality of the cold cathode fluorescent lamp unit 11 can be detected.

In a case where there is an abnormality in the connection state and/or light-off operation and the voltage of the terminal T12 or T13 is lower than the output of the coefficient multiplication circuit 94 (i.e., 80% of the maximum value signal), the output of the comparator 95 or 96 is set to low-level.

When the output of the comparator 92 is set to low-level, the output of the AND gate 99 is set to low-level. When the output of the AND gate 99 is set to low-level, the transistor M11 is turned off. When the transistor M11 is turned off, the capacitor C21 is charged by the current source 111. When the capacitor C21 is charged so that its charge voltage exceeds the reference voltage of the reference voltage source 113, the output of the comparator 112 is set to low-level. When the output of the comparator 112 is set to low-level, the transistor M12 is turned off and the potential of the terminal T14 is set to high-level. When the potential of the terminal T14 is set to high-level, the abnormality of the cold cathode fluorescent lamp unit 11 can be detected.

In a case where an overcurrent state occurs in the cold cathode fluorescent lamp unit 11, and the voltage of the terminal T11 exceeds the reference voltage generated at the reference voltage source 98, the output of the comparator 97 is set to low-level. When the output of the comparator 97 is set to low-level, the output of the AND gate 99 is set to low-level. When the output of the AND gate 99 is set to low-level, the transistor M11 is turned off. When the transistor M11 is turned off, the capacitor C21 is charged by the current source 111. When the capacitor C21 is charged so that its charge voltage exceeds the reference voltage of the reference voltage source 113, the output of the comparator 112 is set to low-level. When the output of the comparator 112 is set to low-level, the transistor M12 is turned off, and the terminal T14 is set to high-level. When the terminal T14 is set to high-level, the abnormality of the cold fluorescent lamp can be detected. The terminal T14 is connected to the terminal T5 of the drive IC 13.

The average value circuit 101 is arranged such that detection voltages V12 and V13 are supplied to its terminals T12 and T13, respectively. The average value circuit 101 generates a signal according to the average value of the detection signals V12 and V13, and outputs the generated signal from a terminal T18. The terminal T18 is connected to the terminal T2 of the drive IC 13.

In the following, the maximum value output circuit 91 according to the present embodiment is described.

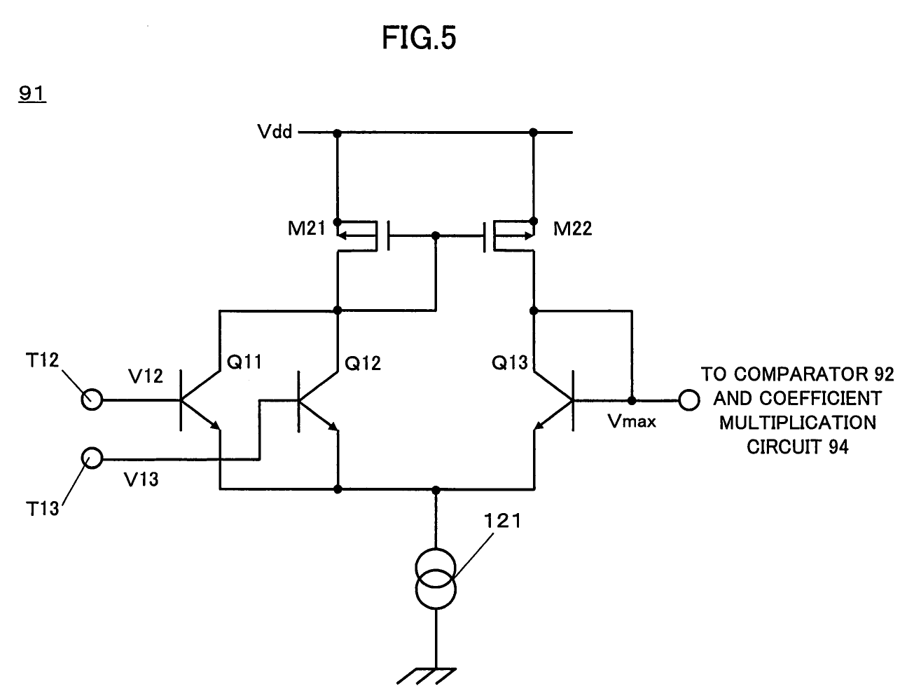

FIG. 5 is a block diagram showing an exemplary configuration of the maximum value output circuit 91.

According to the present example, the maximum value output circuit 91 corresponds to a circuit for selectively outputting the maximum level signal out of detection signals supplied by the terminals T12 and T13, and is realized by bipolar transistors Q11, Q12, Q13, MOS field effect transistors M21 and M22, and a current source 121.

The bipolar transistors Q11, Q12, and Q13 correspond to npn transistors. In one example, the bipolar transistors Q11, Q12, and Q13 are arranged to have substantially the same configuration.

The transistor Q11 corresponds to an input transistor of which a base is connected to the terminal T12, a collector is connected to a gate and a drain of the transistor M21 and a gate of the transistor M22, and an emitter is grounded via the current source 121. The transistor Q11 draws a current from the collector according to the detection signal supplied to the terminal T12.

The transistor Q12 corresponds to an input transistor of which a base is connected to the terminal T13, a collector is connected to the gate and drain of the transistor M21 and the gate of the transistor M22. The transistor Q12 draws a current from the collector according to the detection signal supplied to the terminal T13.

The transistor Q13 corresponds to an output transistor of which a collector is connected to the drain of the transistor M22 and an emitter is grounded via the current source 121. A current according to the currents of the transistors Q11 and Q12 is supplied to the transistor Q13.

The transistors M21 and M22 correspond to p-channel MOS field effect transistors. The transistor M21 is arranged such that a current source voltage Vdd is applied to its source, and its gate is connected to its drain and the gate of the transistor M22. The transistor M22 is arranged such that a current source voltage Vdd is applied to its source, and its gate is connected to the gate and drain of the transistor M21. The transistors M21 and M22 form a current mirror circuit, which is arranged to output a current from the drain of the transistor M22 according to the current drawn from the collector of the transistor Q11 or Q12.

The emitter of the transistor Q13 is grounded via the current source 121. The drain of the transistor M22 and the connection point between the collector and base of the transistor Q13 are set to maximum value outputs. The output of the maximum value output circuit 91 is supplied to the comparator 92 and the coefficient multiplication circuit 94.

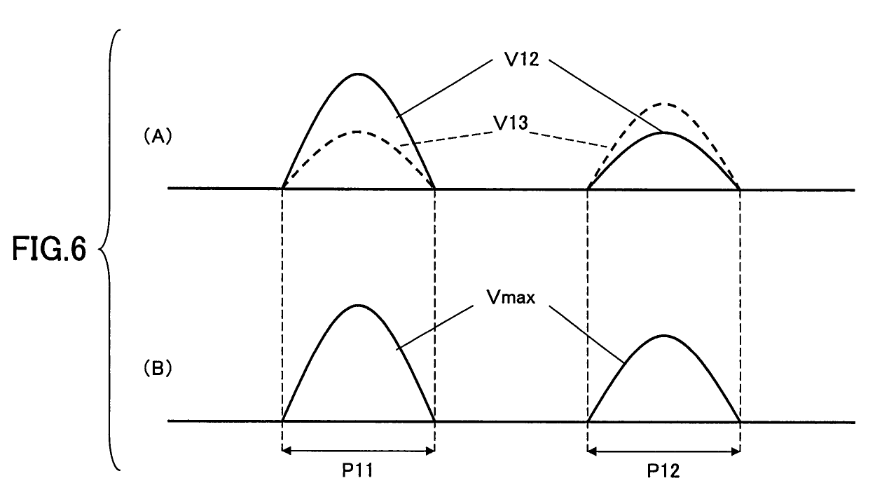

FIG. 6 is a diagram illustrating an operation of the maximum value output circuit 91. It is noted that FIG. 6 (A) represents an input signal, and FIG. 6 (B) represents an output signal.

As is shown in FIG. 6 (A), during period P11, when the detection signal V12 input to the terminal T12 is higher than the detection signal V13 input to the terminal T13, the collector current of the transistor Q11 is sufficiently higher than the collector current of the transistor Q12 owing to the characteristic of the collector current of the bipolar transistor with respect to its base-emitter voltage. In other words, the current output capacity of the transistor Q11 is sufficiently greater than the current output capacity of the transistor Q12.

In this case, since a current from the same current source 121 is drawn from the emitters of the transistors Q11 and Q12, and the current output capacity of the transistor Q11 is sufficiently greater than the current output capacity of the transistor Q12, the current is primarily drawn from the emitter of the transistor Q11 to the current source 121.

It is noted that a current identical to the collector current of the transistor Q11 is supplied to the collector of the transistor Q13 by the current mirror circuit formed by the transistors M11 and M12. In this way, a signal identical to the base signal of the transistor Q11 is generated at the base of the transistor Q13 as is shown in FIG. 6 (B).

As is shown in FIG. 6 (A), during period P12, when the detection signal V13 input to the terminal T13 is higher than the detection signal V12 input to the terminal T12, the collector current of the transistor Q12 is sufficiently higher than the collector current of the transistor Q11 owing to the characteristic of the collector current of the bipolar transistor with respect to its base-emitter voltage. In other words, the current output capacity of the transistor Q12 is sufficiently greater than the current output capacity of the transistor Q11.

In this case, since a current from the same current source 121 is drawn from the emitters of the transistors Q11 and Q12, and the current output capacity of the transistor Q12 is sufficiently greater than the current output capacity of the transistor Q11, the current is primarily drawn from the emitter of the transistor Q12 to the current source 121.

It is noted that a current identical to the collector current of the transistor Q12 is supplied to the collector of the transistor Q13 by the current mirror circuit formed by the transistors M11 and M12. In this way, a signal identical to the base signal of the transistor Q12 is generated at the base of the transistor Q13 as is shown in FIG. 6 (B).

As can be appreciated from the above descriptions, a higher input signal out of the input signals V12 and V13 may be output according to the present example. It is noted that by using bipolar transistors as the input transistors Q11, Q12, and Q13, a large difference may be created between the current output capacities of the transistors Q11 and Q12 according to their respective detection signals V12 and V13 so that the maximum value signal may be accurately output.

It is noted that in the example descried above, the maximum value output circuit 91 is arranged to output a higher signal out of the two input detection signals. However, the present invention is not limited to such as example, and a circuit may be realized for selectively outputting a maximum value signal out of an arbitrary number n of input signals.

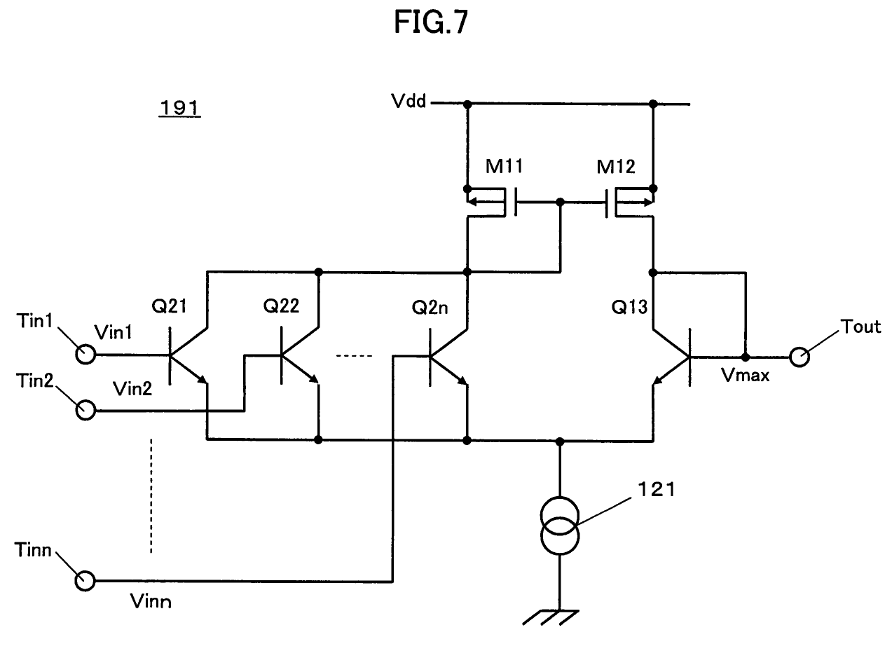

FIG. 7 is a diagram illustrating a modified example of the maximum value output circuit 91. It is noted that in this drawing, elements that are identical to those of FIG. 5 are assigned the same numerical references and their descriptions are omitted.

In the maximum value output circuit 191 according to the present modified example, bipolar transistors Q21˜2n as input transistors are arranged to be parallel with the connection point between the current source 121 and the drain and gate of the transistor M11 and the gate of the transistor M12. According to the present example, detection signals Vin1˜Vinn from terminals Tin1˜Tinn are respectively supplied to the bases of the transistors Q21˜Q2n.

It is noted that in the present example, the maximum value signal out of the signals supplied from the terminals Tin1˜Tinn is arranged to be output from an output terminal Tout. However, the present invention is not limited to such an example, and in an alternative example, the minimum value signal out of the signals supplied from the terminals Tin1˜Tinn may be output from the output terminal Tout.

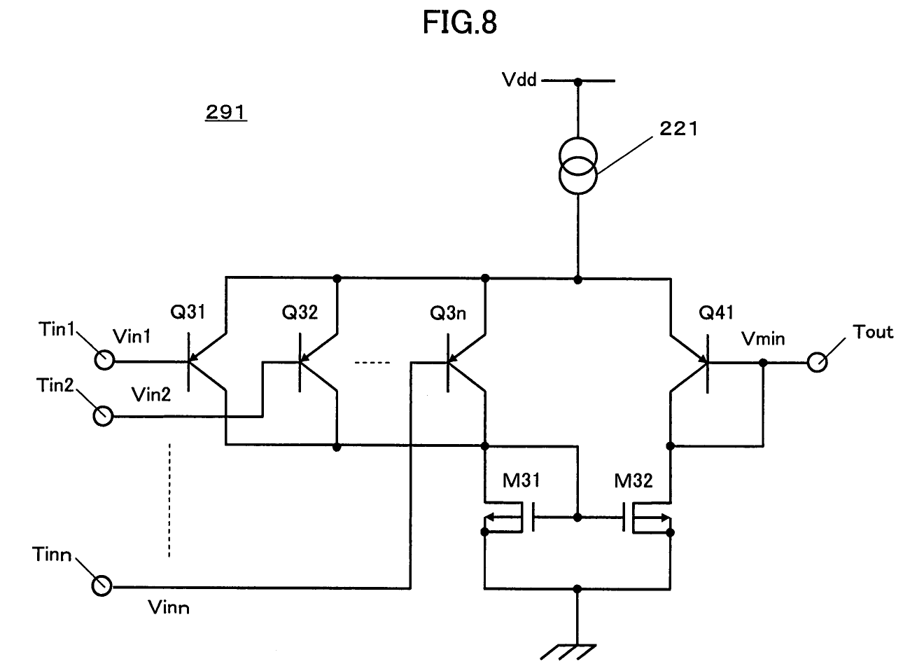

FIG. 8 is a diagram illustrating an exemplary configuration of a minimum value output circuit according to an embodiment of the present invention.

The minimum value output circuit 291 shown in FIG. 8 includes pnp bipolar transistors Q31˜Q3n and Q41, n-channel MOS field transistors M31 and M32, and a current source 221.

According to the present example, the transistors Q31˜Q3n and Q41 are arranged such that their emitters are connected to a power source voltage Vdd via the current source 221, and their collectors are grounded via a current mirror circuit realized by the transistors M31 and M32. Also, signals Vin1˜Vinn from the terminals Tin1˜Tinn are supplied to the bases of the transistors Q31˜Q3n.

The transistors M31 and M32 realize a current mirror circuit that is arranged to draw a current from the collector and base of the transistor Q41 according to the collector current of the transistors M31˜M3n. In this way, the minimum level current out of the currents supplied to the transistors Q31˜Q3n may be supplied to the transistor Q41, and a signal Vmin may be generated at the transistor Q41 that corresponds to the minimum level signal of the signals Vin1˜Vinn supplied from the terminals Tin1˜Tinn to the bases of the transistors Q31˜Q3n. The minimum signal Vmin generated at the base of the transistor Q41 is output from an output terminal Tout.

It is noted that in the illustrative embodiment described above, the maximum value output circuit 91 is used in the cold cathode fluorescent lamp lighting system 1. However, the present invention is not limited to such an embodiment, and for example, the maximum value output circuits 91, 191, and the minimum value output circuit 291 according to embodiments of the present invention may be used in other various systems that implements a circuit for selectively outputting a maximum level signal or a minimum level signal out of plural input signals.

Further, it is noted that the present invention is not limited to the specific embodiments described above, and variations and modifications may be made without departing from the scope of the present invention.

The present application is based on and claims the benefit of the earlier filing date of Japanese Patent Application No. 2004-242472 filed on Aug. 23, 2004, the entire contents of which are hereby incorporated by reference.

What is claimed is:

1. A maximum/minimum value output circuit that selectively outputs a maximum/minimum value signal, the circuit comprising:
a plurality of input transistors having bases that are configured to input differing input signals, and collector-emitter structures that are connected through parallel connection;
a current mirror circuit that outputs a current according to currents at the input transistors; and
an output transistor having the collector-emitter structure to which a current is supplied according to the output current of the current mirror circuit, and a base that outputs a signal corresponding to the maximum or minimum level input signal of the differing input signals input to the bases of the input transistors.

2. The maximum/minimum value output circuit as claimed in claim 1, wherein the input transistors and the output transistor correspond to bipolar transistors.

3. The maximum/minimum value output circuit as claimed in claim 1, wherein the current mirror circuit corresponds to a MOS transistor.

4. The maximum/minimum value output circuit as claimed in claim 1, wherein the input transistors and the output transistor correspond to transistors having essentially identical characteristics.
